(19) United States
(12) Patent Application Publication
(10) Pub. No.: US 2009/0295485 A1
(43) Pub. Date: Dec. 3, 2009

(54) DYNAMICALLY BIASING CLASS AB POWER AMPLIFIERS OVER A RANGE OF OUTPUT POWER LEVELS

(75) Inventor: David A. Mitchell, Waterville, MN (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 12/127,060

(22) Filed: May 27, 2008

(51) Int. Cl. H03G 3/20

(52) U.S. Cl. 330/285

(57) ABSTRACT

A method and apparatus for dynamically biasing a class AB RF power amplifier (PA) over a range of output power levels. A memory 112 holds a table that maps a required output power to the PA from a set of bias point parameters that provide a substantially constant relative power amplifier linearity level for the PA over an output power range of the power amplifier. A bias circuit 104 biases the PA. A processor 106 obtains an output power level from the PA, recalls the bias point table from the memory, maps the power level to the corresponding bias point parameters, and directs the bias circuit to bias the power amplifier in response to the mapped bias point parameters to provide an optimal linearity performance over an operating output power range of the PA.

### FIELD OF THE INVENTION

The present invention relates in general to radio frequency (RF) power amplifiers and, in particular, to dynamically biasing a class AB RF power amplifier over a range of output power levels.

### BACKGROUND OF THE INVENTION

Modem communications systems continue to place ever-increasing performance demands on communications devices. Handheld radiotelephone communications devices in particular are subject to increasingly rigorous demands of smaller size and increased efficiency. At the same time, consumers expect to use these devices more often and for a continuously growing set of features. For example, many handheld phones today allow users to communicate with different types of communications systems, such as cellular systems and local area or wide area network data systems with different RF output power requirements.

Along with an expanded communication network capability, consumers expect phones to be smaller, lighter, and to have longer talk times. Unfortunately, these desirable features often represent competing demands to be satisfied by the phone designer. For example, the simplest method of increasing talk time is to increase battery size, but this works against the goal of smaller size. One method of achieving increased talk time without increasing overall size is to make the device more efficient. This way, talk time as well as other desirable features can be enhanced without increasing the battery size.

Because the power amplifier is by far the largest consumer of power in handheld communications devices, increasing the efficiency of the power amplifier is very desirable. Increased power amplifier efficiency results in the ability to make smaller phones that have more features, including increased talk time. The demand for higher performance communications devices, and in particular, smaller multi-use phones with increased talk time, presents the phone designer with a difficult problem: how to design a power amplifier capable of operating efficiently over a wide range of output power levels for different types of communications systems.

One solution to the problem is to modify the input signal to the amplifier to effectively increase the linear power level of the amplifier. For example, peak suppressing (crest factor reduction) and pre-distorting the input signal to wireless amplifiers can improve the effective linearity of the amplifier by dynamically increasing the compression point which subsequently improves the efficiency of the amplifier. The peak suppression/expansion and pre-distortion circuit uses samples of the output of the amplifier to adaptively adjust a lookup table that is used to pre-distort the signal. The input and output of the peak suppression/expansion and pre-distortion circuit are at the amplifier frequency. However, this solution requires expensive additional peak suppression and pre-distortion circuitry, and does not address efficiency at lower output powers and is very complicated to implement.

Another solution provides a circuit for biasing an amplifying transistor to obtain a conduction angle of less than 180°. The DC bias circuit includes a dynamic biasing circuit for decreasing the DC bias signal provided to the amplifying transistor as the input signal to the power amplifier circuit increases. This configuration permits the amplifier circuit to operate as a linearized Class C amplifier, having a substantially linear input-output relationship similar to that of a Class B amplifier, but with increased operating efficiency. Another solution provides the same benefit for class E amplifiers however, neither of these solutions are applicable to modern digital communication systems such as WIMAX or 3G because the inherent EVM (error vector magnitude) will be too high to support these systems with class B, C, & E amplifiers.

Another solution provides efficient power amplification over a wide dynamic range and for a number of modulation formats by including a carrier amplifier and a peaking amplifier. The carrier amplifier operates with a bias generated by an envelope detector which amplifies the envelope of an input signal and is summed into the amplifier bias network. The peaking amplifier operates with a fixed bias. The outputs of the carrier amplifier and the peaking amplifier are combined using an impedance transforming network. The envelope amplifier can be turned on for high efficiency low power level operation, or it can be turned off for standard Doherty-type operation. Although this solution is an improvement in the art, it still requires numerous additional circuits which add cost and complexity.

Another solution provides dynamically biased circuits where the amplifier bias current is varied according to input signal amplitude to improve efficiency. Benefits include reduced power dissipation, lower EVM, and increased dynamic range. The techniques can be employed in various types of circuits such as, for example, amplifiers, log-domain circuits, and filters. A more specific implementation uses adaptive bias techniques to vary the quiescent current and supply voltage across the power amplifiers in sympathy with the average or instantaneous RF power requirements. By employing a hybrid combination of adaptive bias and linearization, this solution improves amplifier efficiencies over a range of RF powers for a varied type of modulation scheme. However, this solution requires a linearizer circuit to provide an error signal indication that is used to determine the optimum bias conditions for the power amplifier while maintaining an acceptable distortion. These solutions require additional circuitry, which adds cost, and do not provide a wide power-range solution for class AB operation of handheld communication devices.

Accordingly, there is a significant need for a power amplifier capable of maintaining high efficiency while operating sufficiently linear over a wide range of output power levels. It would also be of benefit to provide a class AB mode of operation with a low-cost solution.

### BRIEF DESCRIPTION OF THE DRAWINGS

The invention is pointed out with particularity in the appended claims. However, other features of the invention will become more apparent and the invention will be best understood by referring to the following detailed description in conjunction with the accompanying drawings in which:

FIG. 1 illustrates a simplified block diagram of a power amplifier circuit, in accordance with the present invention;

FIG. 2 illustrates a method, in accordance with the present invention;

FIG. 3 shows a graph of an improvement provided by the present invention; and

FIG. 4 shows another graph of an improvement provided by the present invention.

Skilled artisans will appreciate that common but well-understood elements that are useful or necessary in a commercially feasible embodiment are typically not depicted or described in order to facilitate a less obstructed view of these various embodiments of the present invention.

### DETAILED DESCRIPTION OF THE PREFERRED EMBODIMENT

The present invention provides an RF power amplifier with relative high efficiency over a wide range of output power levels. In addition, the present invention helps solve the above-identified problems by implementing a low-cost power amplifier biasing method capable of providing a nearly constant error vector magnitude output over a wide range of RF output power levels.

In particular, the present invention describes biasing a class AB radio frequency (RF) power amplifier (PA) for a relatively constant efficiency and substantially constant EVM (error vector magnitude) over a range of PA power output levels. In particular, the present invention keeps the relative intermodulation distortion (IMD) levels of a power amplifier substantially constant over a range of output power levels of the power amplifier. As used herein, the term “relative” means that the IMD levels expressed in dBc are held substantially constant no matter what the actual power output of the PA is.

By definition of RF amplifier physics, as is known to a person having ordinary skill in the art, if the relative intermodulation distortion can be held constant no matter what the RF power level is, the EVM and efficiency will be held relatively constant as well.

In terms of mathematical principles, efficiency and EVM are directly related to the amount of IMD an amplifier produces. The different classes of amplifiers such as class A or AB and how they are defined measure how much of the time the actual transistor conducts. In the present invention, the conduction angle is held constant (somewhere between 181 and 359 degrees) which is the definition of a class AB amplifier, to maintain a substantially constant relative PA linearity level by dynamically re-biasing the PA for each discreet output power level of the PA which in turn keeps the ‘relative’ (not absolute) distortion (linearity) level performance constant as well.

As a result, the present invention reduces battery consumption of any mobile communications device used in a system with automatic gain control (AGC) up to 20%. As described herein, a potential power savings for an actual WiMAX IEEE 802.16e modem is demonstrated. However, it should be recognized that the present invention is applicable to many different devices capable of communications. Examples include, but are not limited to, mobile terminals, individual subscriber units in a satellite communications system, amateur radios, business band radios, cellular phones, and the like.

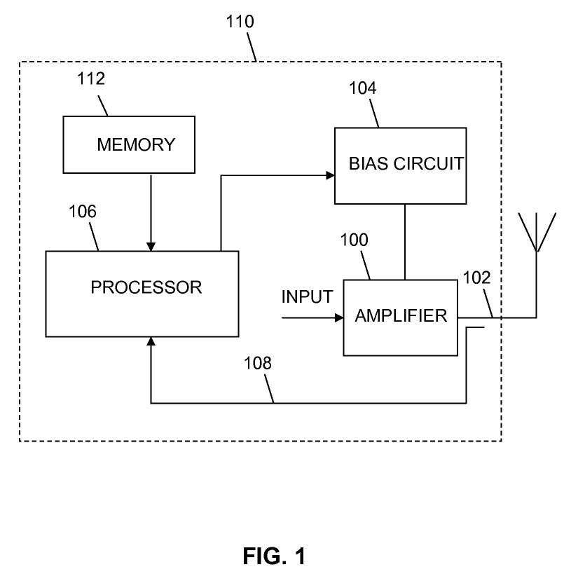

FIG. 1 shows a diagram of a power amplifier circuit in accordance with a preferred embodiment of the present invention. The power amplifier circuit includes a class AB transmitter power amplifier (PA) 100 which has an input and an output 102. The PA 100 is coupled to the existing bias circuit 104 and a processor operable in accordance with the present invention. The processor is also operable to monitor 108 the output 102 of the PA 100 through common PA detector circuits. However, it should be recognized that the bias circuit 104 could directly monitor the output 102. As shown, the PA is operable within a communication device 110. However, the present invention is applicable to any device application using a class AB power amplifier, and particularly provides a substantially constant relative PA linearity level, i.e. substantially constant efficiency/EVM (Error Vector Magnitude of the transmit output), as a way to prolong battery life for mobile devices in Time Division Duplexing (TDD) or Frequency Division Duplexing (FDD) systems that use class AB RF power amplifiers.

Almost all digital radio communications systems such as WiMAX and 3G cellular require that a handset's RF power be turned down as the signal-to-noise ratio (SNR) increases so the amount of sideband noise can be kept to a minimum and also to keep a base station receiver from overload. In simpler terms, the closer the communication device is to the base station, the less transmit signal the communication device requires in order for the base station to receive the signal. The present invention relies on this basic fact of modern communication systems.

In operation, the present invention keeps the relative PA linearity level (e.g. SNR of the transmit output signal or EVM) constant over a range of RF output power for a mobile communication device. As an example, the SNR of the output signal of a 64 QAM OFDM signal requires a 26 dB EVM (typical of IEEE 802.16e) to be sufficiently decoded by a base station receiver. Most PAs in mobile communications devices are designed to barely meet this specification at the highest RF power out required by the system specification, for cost, size and other factors. In actual operation, a handset may rarely be operating at this output power depending on many factors. If subscribers are making a cell phone call or are using a PDA to download web pages in a densely covered RF area, the PA may be operating well below its maximum power output capability due to the gain control algorithm of the system. If the PA could be held to a constant relative PA linearity level at lower power out the PA device will dissipate less power and thus less current will be required from the batteries of the device. The battery life between charging may be prolonged significantly and talk time will be increased as well.

A PA in class AB operation requires the RF signal to drive the device partially into compression causing the RF transistor current of the PA to increase. The effect is that the input RF signal turns the part ‘on’ harder causing the bias point to change. As a result, the RF output power increases faster than the DC consumption of the device so the efficiency of the PA increases. However, the linearity and EVM degrades because the PA is driving towards compression as compared to a class A amplifier which operates like a small signal transistor. As the output power of the PA is decreased, the class of operation for the device trends towards class A and the efficiency of the device drops significantly. The lower efficiency effectively reduces the battery capacity compared to keeping the efficiency constant versus RF power output as the PA is dissipating energy into the phone in the form of wasted heat for no real reason.

By changing the bias point of the PA dynamically with respect to the required system RF output power, in accordance with the present invention, the PA linearity and EVM are held substantially constant thus holding the transistor in efficient class AB operation regardless of the absolute power output of the device. This is done by decreasing the current and voltage applied to the device so the relative PA linearity and EVM performance is substantially constant no matter what the output power level is. Therefore, the base station will still receive an adequate signal to decode the transmitted signal, but the power dissipation of the mobile device is lowered.

The preferred way to implement this power saving technique is to characterize the PA during the manufacturing process. As will be demonstrated below, a significant power savings comes from the first 4 dB of power control. Most digital communications systems power control architecture typically uses discreet one dB steps. One dB steps are typically enough resolution for the system to function properly and give the desired performance of the system.

While in the manufacturing process, a test and tuning system could measure how accurate the power control is for the first 5 to 10 dB of the power range of the PA. This is because the PA is near compression during this upper range (near rated power output) and the steps will not be exactly 1 dB. The power is measured over the operating frequency range of the device and the first 5-10 dB of output range giving the opportunity to implement the present invention. The PA bias circuit 104 could be easily configured by parameters to control the collector and reference voltages discreetly as in the test shown. In addition, the PA can be characterized to obtain the limits used to control those parameters.

A lookup table could be built and written in memory 112 of the processor 106 or to a flash memory, Electrically Erasable Programmable Read Only Memory (EEPROM), or other memory apparatus of the RF device 110, during tuning of the radio at manufacturing test, for use by the run time code in the processor 106 during actual operation. The lookup table can include a bias point table that provides the proper voltage and current to bias the PA for substantially constant PA linearity and EVM for each one dB drop in RF power output. In particular, the bias point table maps a discreet DC power level to the power amplifier from a set of bias point parameters that provide a substantially constant PA linearity and EVM of the power amplifier output over an operating output power range of the power amplifier. Having a constant operating EVM would provide relatively high efficiency across the PA power band.

There need be no real time instantaneous biasing of the PA controlled by the processor 106. The bias condition would simply be recalled by the processor 106 from the table in the memory 112 to determine the proper parameters defined in the table in response to the system AGC RF power requirement. That power level and bias point would be maintained until the system required the power to change again 108. The processor 106 can then set the required output power level from the corresponding bias point parameters in the table. The processor 106 can then direct the bias circuit 104 to provide the proper bias to the PA 100 in response to the mapped bias point parameters to provide a substantially optimal efficiency over an operating output power range of the power amplifier.

All WiMAX mobile and CPE devices require a calibrated power detector at the output 108 of the PA 100 due to the strict system requirements of the standard near rated power output, and this existing detector can be used as feedback to monitor the output power level to ensure the proper bias conditions from the table are being used to provide a substantially constant EVM for that output power level.

Another useful aspect of the present invention is collaboration with the PA device vendor. To ensure frequency and gain stability over temperature of the device due to the changing load line of the transistors, the PA devices could be characterized to function with the proper specifications for the present invention as well as compensate for frequency and gain stability over temperature, and have these parameters stored in the memory for recall and application to the PA 100 by the microprocessor to the bias circuit 104.

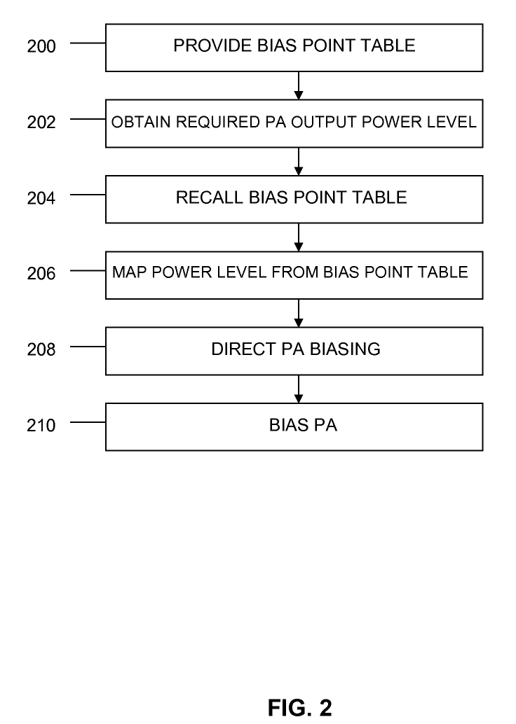

FIG. 2 shows a flowchart for a method of dynamically biasing a power amplifier over a range of output power levels, in accordance with a preferred embodiment of the present invention, which includes a first step 200 of providing a bias point table in a memory that maps the desired output power level required by the system from a set of previously determined bias point parameters which provide a substantially constant linearity performance of the power amplifier output over an operating output power range of the power amplifier. In particular, the PA linearity level correlates to an EVM or an efficiency, wherein the bias table of the PA can be configured for a substantially constant EVM or efficiency.

A next step 202 includes obtaining the required RF output power level determined by the system based on the mobile devices signal-to-noise with the base station. This step can also include verifying the output power level of the power amplifier from a power detector.

A next step 204 includes recalling the bias point table from the memory.

A next step 206 includes mapping the required output power level from the corresponding associated bias point parameters from the table.

A next step 208 includes directing a circuit to discreetly bias the power amplifier in response to the mapped bias point parameters.

A next step 210 includes biasing the power amplifier to provide a substantially optimal linearity performance over an operating output power range of the power amplifier.

Advantageously, the method and apparatus of the present invention as described is a versatile way of achieving high efficiency power amplifier operation while satisfying Federal Communications Commission (or any other regulatory agency) compliance requirements, while also providing a low cost class AB amplifier configuration. The increased efficiency allows communications devices to be built smaller and lighter while increasing talk time and times between charging.

In addition, there is no need for expensive external components for the present invention such as A/D converters or complicated real time dynamic feedback loops as is necessary for prior art pre-distortion methods, etc. Only minor software changes at the physical layer radio control to implement the present invention will be needed. Also, there would be a small amount of time added to the test and tuning procedure in the factory for the present invention. By implementing the invention the PA cost would probably not go up at all if a custom MMIC design could be implemented and characterized using the present invention while using common resistors and capacitors which are commodity parts and are very inexpensive.

### EXAMPLE 1

The present invention was implemented in a actual communication device.

The test platform for this was a Motorola CPEi-100 IEEE 802.16e compliant modem. This is a fully functional WiMAX customer premise equipment (CPE) with a power amplifier capable of a +28 dBm power output. The unit passes EVM and FCC requirements at this power output with margin as the data below shows. A WiMAX mobile communication device was not used, however, the purpose of this experiment was to show how this idea can be successfully implemented on a mobile device platform.

The RF frequency of operation was 2.600 GHz. The PA device is manufactured by Mitsubishi Electric (p/n. MGFS36E2527). This RF device is a three stage low voltage Heterojunction Bipolar transistor (HBT) process monolithic microwave integrated circuit (MMIC). This part has internal active bias.

The output signal is OFDMA 512 FFT 64 QAM and 5 MHz wide. An external power supply was connected to the collector leads of the device (Vc) so that the collector voltage could be tuned. The base reference voltage (Vref) was also connected to a separate external supply for ease of adjustment. The duty cycle of the power amplifier was set to 37.4% with transmit on time of 1.87 ms. This is a typical duty cycle for a WiMAX CPE to obtain 1 Mbits/s uplink data rate.

The unit was measured at its rated output power of +28 dBm. The following parameters were then measured: Vc, Ic, Vref, EVM, and FCC mask compliance, where Vc is the collector voltage of the PA, Ic is the collector current of the PA, Vref is the reference voltage for the active bias of the PA, and EVM is the error vector magnitude of the transmit signal. From these numbers the power dissipation and efficiency of the PA was calculated. Then the output power was reduced to +27 dBm using the power control feature of the unit. All of the parameters were measured again giving data of how the unit would typically be operated in the field and how the PA trends towards class A operation.

Then the collector voltage was reduced and Vref lowered to get back to the same EVM as when at +28 dBm. All of the parameters were measured again. This process is continued 1 dB at a time and the collector voltage and Vref modified for several power readings down to +24 dBm. In the Tables below all of the data is shown. The tests corresponding to the various measurements to verify FCC compliance were spectrally pure.

Table 1 below shows the test data. The data was taken under two separate test conditions. In most applications of power control in a communications system as are done in the prior art, the PA bias is unchanged no matter the output power. This is the first condition tested. The second set of data in Table 1 is using the technique in accordance with the present invention. Table 2 shows a comparison of the results of the data.

TABLE 1
Test Data

| | | | | | | | |
|---|---|---|---|---|---|---|---|
| Vc (Vdc) | Ic (A) | Vref (Vdc) | Po (mW) | Po (dBm) | Eff (%) | EVM (dB) | Pdis (W) |

PA Measured In a Prior Art Application at 2.6 GHz

| | | | | | | | |
|---|---|---|---|---|---|---|---|
| 6.00 | 0.400 | 2.85 | 0.631 | 28.0 | 26.3 | −30.8 | 2.400 |
| 6.00 | 0.372 | 2.85 | 0.501 | 27.0 | 22.5 | −34.0 | 2.232 |
| 6.00 | 0.353 | 2.85 | 0.398 | 26.0 | 18.8 | −34.3 | 2.118 |
| 6.00 | 0.334 | 2.85 | 0.316 | 25.0 | 15.8 | −35.2 | 2.004 |
| 6.00 | 0.319 | 2.85 | 0.251 | 24.0 | 13.1 | −36.0 | 1.914 |

PA Measured Using The Present Invention at 2.6 GHz

| | | | | | | | |
|---|---|---|---|---|---|---|---|
| 6.00 | 0.400 | 2.85 | 0.631 | 28.0 | 26.3 | −30.8 | 2.400 |
| 5.32 | 0.355 | 2.85 | 0.501 | 27.0 | 26.5 | −30.8 | 1.889 |
| 4.70 | 0.322 | 2.85 | 0.398 | 26.0 | 26.3 | −29.6 | 1.513 |
| 4.20 | 0.234 | 2.63 | 0.316 | 25.0 | 32.2 | −28.9 | 0.983 |
| 4.00 | 0.188 | 2.54 | 0.251 | 24.0 | 33.4 | −29.2 | 0.752 |

TABLE 2
Results Comparison

| | | Pdis improvement | | | |
|---|---|---|---|---|---|
| | | referenced from | | Overall Pdiss | |
| | | max Po (W) | | improvement using the | |
| | | | Constant | constant EVM Method | |
| Po (mW) | | Typical | EVM | (W) | % Improvement |
| Max | 0.631 | * | * | 0 | 0.00 |
| Max - 1 dB | 0.501 | 0.168 | 0.511 | 0.343 | 32.85 |
| Max - 2 dB | 0.398 | 0.282 | 0.887 | 0.605 | 31.81 |
| Max - 3 dB | 0.316 | 0.396 | 1.417 | 1.021 | 27.94 |
| Max - 4 dB | 0.251 | 0.486 | 1.648 | 1.162 | 29.49 |

The above test results reveal that implementing the technique of the present invention can save significant power dissipation in the PA while transmitting. The overall power savings in watts is high and the percent improvement over comparable operating conditions is significant as well.

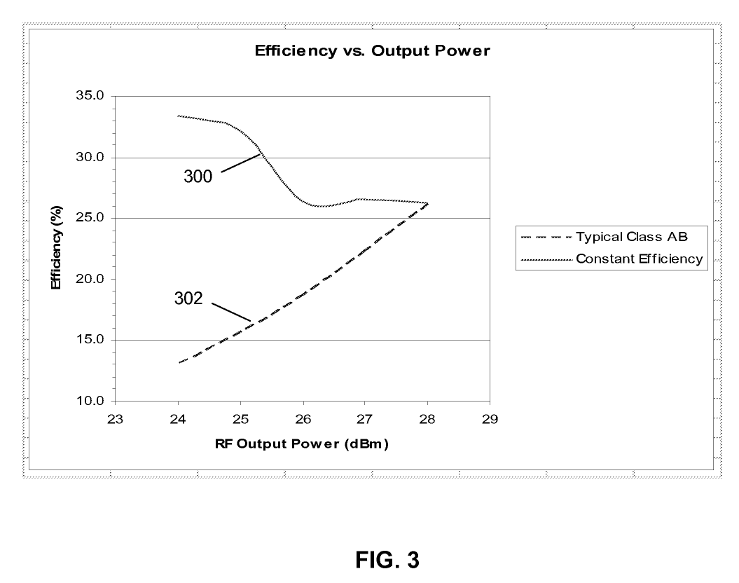

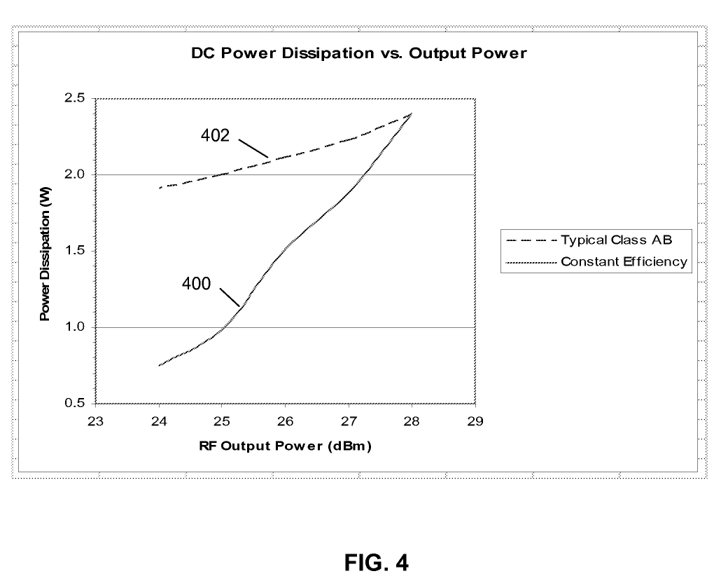

FIGS. 3 and 4 show how the efficiency is improved and how the power dissipated in the RF amplifier is decreased using the present invention. In FIG. 3, the present invention shows much improved efficiency 300 at output power levels lower than the rated power level of the PA over the efficiency 302 of a typical Class AB power amplifier. In FIG. 4, the present invention shows much improved power dissipation 400 at output power levels lower than the rated power level of the PA over the power dissipation 402 of a typical Class AB power amplifier, in some cases by over 50%.

### EXAMPLE 2

If the data above is applied to a real life application of a 3G cell phone and assuming the PA behaves similarly, there is a potential increase in battery life, thus increasing talk time and the time between charging. This increase in battery life reduces the dependence on Li-Ion battery designers finding a way to increase battery efficiency and capacity to lengthen the time between charges, and phone designers finding ways to save power through complicated sleep mode techniques and other methods. The power amplifier is the single most inefficient device in a communication device when it is on. During a call a typical cell phone will generate waste heat primarily due to the PA inefficiency. This present invention addresses these problems.

A hypothetical calculation shows significant battery life improvement before recharging needs to take place. If it is assumed that the PA power output of a typical phone is +24 dBm maximum, the data above can be used to extrapolate a potential scenario. Most phones will need about 1 Watt of power to operate all other circuitry required while a phone call is taking place. From the measured data above for +24 dBm using the constant EVM technique the PA will need 0.752 watts. If the phone user has an adequate signal such that the system tells the phone to reduce its power 4 dB the power savings can be estimated from the present invention as:
Power used at +24 dBm=1.752 Watts (PA efficiency˜32% 1 Watt plus the PA power dissipation of 0.752 Watts)
Power used at +20 dBm˜1.625 Watts (PA efficiency˜16% typical Class AB with no compensation. PA efficiency degrades about 50% the first 4 dB power control.)
Power used at +20 dBm˜1.303 Watts (PA efficiency˜32% using the constant EVM/efficiency of the present invention)
   where the % power savings=(1.625-1.303)/1.625*100=19.8%

As this simple calculation shows, the potential power savings while the phone is transmitting is almost 20% using the present invention. This would have a large impact on the battery capacity while transmitting.

This power savings will come with a distribution of users with sufficient signal to cause the base station to tell those units to transmit less RF power. There are many system studies to obtain that data, but is outside the scope of the present invention. With WiMAX type systems in a densely deployed area such as inner cities and urban developments, the percentage of users backing down their power is about 50%. For example, most digital radio systems such as WiMAX and 3G require a certain SNR to transmit and receive data at the highest modulation level or data rate which is the most spectrally efficient manner to receive and transmit any digital signal. Service providers like to have as many users as possible transmit and receive data at the highest rate possible. This allows them to load infrastructure equipment with more users reducing the infrastructure cost to the service provider. There is generally enough gain built into the system that most users have considerable margin of this SNR. This present invention relies on this fact since if most users have sufficient SNR to receive and transmit data at the highest data rate that would mean the user has adequate signal level from the base station. The mobile device RF power is usually reduced by the system automatically when this happens. Sometimes up to 20 dB or more. The drawback of this in power consumption is that the power amplifier operating point usually becomes class A. Class A amplifiers are the most inefficient but most distortion free amplifier that can be designed. However, the power amplifier does not need to be that linear and still do the job. By dynamically biasing the power amplifier to operate in Class AB mode over a large range of RF power output, in accordance with the present invention, the DC (direct current) consumption will be reduced considerably and thus efficiency of the power amplifier can be held relatively high. The EVM of the PA will be adequately sufficient for optimal throughput and system operation. Since less DC power is consumed for most users of the system, the battery life of the device is extended, prolonging the time between battery charges. This idea also reduces the heat dissipation in the device.

There are other benefits to lowering the heat dissipation. The PA mean time to failure (MTTF) will be reduced as the heat dissipation in the device is lower on average. The mobile device itself will be subject to less thermal stress and many users of these types of devices complain the unit gets warm or hot while in use. The present invention could even provide for smaller mobile products. If the average power dissipation of the device is lowered, the product package could be made smaller. Conversely, more features could be added for the customer experience with the extra available power.

In summary, by simply redefining how a power amplifier is biased and giving the device only the DC power it needs to function at the given operating condition it is possible to increase the effective battery capacity of any mobile RF digital communication device using class AB type amplifiers if the communications system uses AGC. The concept of maintaining a constant EVM and/or efficiency of the power amplifier output over a range of RF output power was proven to be effective as demonstrated herein. Using well characterized power amplifiers and careful design implementation it may be possible to decrease the average power dissipation of a mobile device by up to 20% or even more as this technology is developed further.

It will be understood that the terms and expressions used herein have the ordinary meaning as is accorded to such terms and expressions by persons skilled in the field of the invention as set forth above except where specific meanings have otherwise been set forth herein.

The sequences and methods shown and described herein can be carried out in a different order than those described. The particular sequences, functions, and operations depicted in the drawings are merely illustrative of one or more embodiments of the invention, and other implementations will be apparent to those of ordinary skill in the art. The drawings are intended to illustrate various implementations of the invention that can be understood and appropriately carried out by those of ordinary skill in the art. Any arrangement, which is calculated to achieve the same purpose, may be substituted for the specific embodiments shown.

The invention can be implemented in any suitable form including hardware, software, firmware or any combination of these. The invention may optionally be implemented partly as computer software running on one or more data processors and/or digital signal processors. The elements and components of an embodiment of the invention may be physically, functionally and logically implemented in any suitable way. Indeed the functionality may be implemented in a single unit, in a plurality of units or as part of other functional units. As such, the invention may be implemented in a single unit or may be physically and functionally distributed between different units and processors.

Although the present invention has been described in connection with some embodiments, it is not intended to be limited to the specific form set forth herein. Rather, the scope of the present invention is limited only by the accompanying claims. Additionally, although a feature may appear to be described in connection with particular embodiments, one skilled in the art would recognize that various features of the described embodiments may be combined in accordance with the invention. In the claims, the term comprising does not exclude the presence of other elements or steps.

Furthermore, although individually listed, a plurality of means, elements or method steps may be implemented by e.g. a single unit or processor. Additionally, although individual features may be included in different claims, these may possibly be advantageously combined, and the inclusion in different claims does not imply that a combination of features is not feasible and/or advantageous. Also the inclusion of a feature in one category of claims does not imply a limitation to this category but rather indicates that the feature is equally applicable to other claim categories as appropriate.

Furthermore, the order of features in the claims do not imply any specific order in which the features must be worked and in particular the order of individual steps in a method claim does not imply that the steps must be performed in this order. Rather, the steps may be performed in any suitable order. In addition, singular references do not exclude a plurality. Thus references to “a”, “an”, “first”, “second” etc do not preclude a plurality.

What is claimed is:

1. A class AB power amplifier circuit that is dynamically biased over a range of output power levels, the circuit comprising:
a memory for holding a bias point table that maps a required output power level to the power amplifier from a set of bias point parameters that are used to provide a substantially constant relative power amplifier EVM level for the power amplifier over an operating output power range of the power amplifier;
a bias circuit operable to bias the power amplifier; and
a processor coupled to the memory, the processor operable to obtain an output power level of the power amplifier, recall the bias point table from the memory, map the required output power level from the corresponding bias point parameters in the table, and direct the bias circuit to bias the power amplifier in response to the mapped bias point parameters to provide a substantially optimal linearity performance over an operating output power range of the power amplifier.

2. The circuit of claim 1, wherein the relative power amplifier linearity level comprises an amplifier efficiency.

3. The circuit of claim 1, wherein the relative power amplifier linearity level comprises an EVM.

4. The circuit of claim 1, wherein the power amplifier comprises an RF amplifier.

5. The circuit of claim 1, wherein the bias point parameters include a collector voltage of the power amplifier.

6. The circuit of claim 1, wherein the bias point parameters include a collector current of the power amplifier

7. The circuit of claim 1, wherein the bias point parameters include a voltage reference for the active bias of the power amplifier.

8. A communication device incorporating a class AB RF power amplifier circuit that is dynamically biased over a range of output power levels, the circuit comprising:
a memory for holding a bias point table that maps the required RF output power level to the power amplifier from a set of bias point parameters that provide a substantially constant error vector magnitude of the power amplifier output over an operating output power range of the power amplifier;
a bias circuit operable to bias the power amplifier; and
a processor coupled to the memory, the processor operable to obtain an output power level of the power amplifier, recall the bias point table from the memory, map the required output power level from the corresponding bias point parameters in the table, and direct the bias circuit to bias the power amplifier in response to the mapped bias point parameters to provide a substantially constant intermodulation distortion levels over an operating output power range of the power amplifier.

9. The device of claim 8, wherein the bias point parameters include a collector voltage of the power amplifier.

10. The device of claim 8, wherein the bias point parameters include a collector current of the power amplifier

11. The device of claim 8, wherein the bias point parameters include a voltage reference for the active bias of the power amplifier.

12. A method for dynamically biasing a class AB RF power amplifier over a range of output power levels, the method comprising the steps of:
providing a bias point table in a memory that maps a required RF output power level to the power amplifier from a set of bias point parameters that are used to provide a substantially constant relative power amplifier linearity level for the power amplifier over an operating output power range of the power amplifier;
obtaining an output power level of the power amplifier;
recalling the bias point table from the memory;
mapping the required output power level from the corresponding bias point parameters from the table;
directing a bias circuit to bias the power amplifier in response to the mapped bias point parameters; and
biasing the power amplifier to provide a substantially optimal linearity performance over an operating output power range of the power amplifier.

13. The method of claim 12, wherein the relative power amplifier linearity level of the providing step comprises an amplifier efficiency.

14. The method of claim 12, wherein the relative power amplifier linearity level of the providing step comprises an EVM.

15. The method of claim 12, wherein in the providing step the bias point parameters include a collector voltage of the power amplifier.

16. The method of claim 12, wherein in the providing step the bias point parameters include a collector current of the power amplifier

17. The method of claim 12, wherein in the providing step the bias point parameters include a voltage reference for the active bias of the power amplifier.
